(19) United States
(12) Patent Application Publication
(10) Pub. No.: US 2020/0224312 A1
(43) Pub. Date: Jul. 16, 2020

(54) DEPOSITION AND TEXTURE CONTROL OF PBTIO3, PBZRO3, AND PBZRXTI1-XO3

(71) Applicant: U.S. Army Combat Capabilities Development Command, Army Research Labortary, Adelphi, MD (US)

(72) Inventors: Nicholas A. Strnad, Laurel, MD (US); Daniel M. Potrepka, Silver Spring, MD (US); Ronald G. Polcawich, Derwood, MD (US)

(21) Appl. No.: 16/738,203

(22) Filed: Jan. 9, 2020

Related U.S. Application Data
(60) Provisional application No. 62/790,489, filed on Jan. 10, 2019.

(51) Int. Cl. C23C 16/455; H01L 41/316; H01L 41/187; C23C 16/56; C23C 16/40

(52) U.S. Cl. CPC C23C 16/45527; H01L 41/316; C23C 16/409; H01L 41/1875; C23C 16/56; H01L 41/1876

(57) ABSTRACT

A method of depositing a thin film of lead titanate (PTO), lead zirconate (PZO) or lead zirconate titanate (PZT) comprising depositing a PTO, PZO or PZT layer upon a substrate whereby growth occurs primarily due to self-limited surface chemisorption of pulsed chemical vapor, and annealing the PTO, PZO, or PZT layer and substrate.

### RELATED APPLICATION

This application claims benefit to U.S. Provisional Patent Application Ser. No. 62/790,489, filed Jan. 10, 2019, entitled “Atomic Layer Deposition and Texture Control of PbTiO₃, PbZrO₃, and PbZᵣₓTi₁₋ₓO₃,” which is hereby incorporated herein in its entirety.

### GOVERNMENT INTEREST

The invention described herein may be manufactured, used, and licensed by or for the U.S. Government.

### BACKGROUND

### Field

Embodiments of the present invention generally relate to thin film deposition and, more specifically, to deposition techniques for depositing thin films of lead titanate (PTO), lead zirconate (PZO) or lead zirconate-titanate (PZT).

### Description of the Related Art

Lead zirconate-titanate (PZT) films crystallized in the perovskite phase near the morphotropic phase boundary exhibit a very high dielectric constant and extremely large piezoelectric coefficients. For those reasons among others, PZT is a ubiquitous and technologically useful material. Decades have been spent developing and refining thin film deposition techniques for PZT; however, those techniques have typically yielded planar films (sputtering, pulsed-laser deposition, sol-gel) with few exceptions, such as off-angle sputtering, chemical vapor deposition. Atomic layer deposition (ALD) is a technique that can enable film deposition into micro-machined or self-assembled trenches and pores with very high aspect-ratios exceeding 50:1. A reliable ALD process to deposit high-quality PZT into micro-machined or self-assembled trenches and pores is desired to overcome the boundary posed by planar film deposition techniques.

Several attempts have been made to develop a reliable process to deposit high-quality PTO and PZT by ALD over the past 12 to 15 years. However, none of these techniques have shown to produce repeatable commercially viable results having preferred electrical characteristics.

Therefore, there is a need in the art for improved techniques to deposit thin films of PTO, PZO, and PZT on non-planar surfaces.

### SUMMARY

A method of depositing a thin film of lead titinate (PTO), lead zirconate (PZO) or lead zirconate titanate (PZT) comprising depositing a PTO, PZO or PZT layer upon a substrate whereby growth occurs primarily due to self-limited surface chemisorption of pulsed chemical vapor, and annealing the PTO, PZO, or PZT layer and substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a diagram of an atomic layer deposition super-cycle used in one embodiment of the invention to deposit thin films of PTO, PZT, or PZO;

FIG. 2 depicts one embodiment of the ALD process flow;

FIG. 3 depicts the details of a binary PbOₓ sub-cycle in accordance with an embodiment of the invention;

FIG. 4 depicts the details of a binary TiOₓ sub-cycle in accordance with an embodiment of the invention;

FIG. 5 depicts the details of a binary ZrOₓ sub-cycle in accordance with an embodiment of the invention;

FIG. 6 is a graphical representation of an atomic layer deposition formation of a PZT layer followed by a rapid thermal anneal step in accordance with an embodiment of the invention;

FIG. 7 is a graphical representation of an atomic layer deposition formation of second PZT layer on the layer formed in FIG. 6 followed by a rapid thermal anneal step in accordance with an embodiment of the invention;

FIG. 8 is a representation of a PbTiO₃ super-cycle in accordance with an embodiment of the invention;

FIG. 9 is a representation of a PbZrO₃ super-cycle in accordance with an embodiment of the invention;

FIG. 10 is a representation of a PbZrₓTi₁₋ₓO₃ super-cycle in accordance with an embodiment of the invention;

FIG. 11 is a representation of a first alternate PbZrₓTi₁₋ₓO₃ super-cycle in accordance with an embodiment of the invention;

FIG. 12 is a representation of a second alternate PbZrₓTi₁₋ₓO₃ super-cycle in accordance with an embodiment of the invention;

FIG. 13 is a representation of a third alternate PbZrₓTi₁₋ₓO₃ super-cycle in accordance with an embodiment of the invention;

FIG. 14 is a scanning tunneling electron microscope (STEM) image of a cross-section of an unannealed PTO sample produced in accordance with an embodiment of the invention;

FIG. 15 is a STEM image of a cross-section of an annealed PTO sample produced in accordance with an embodiment of the invention;

FIG. 16 is a graph of X-Ray diffraction produced by a PTO layer created using several different anneal protocols in accordance with an embodiment of the invention;

FIG. 17 is a graph created by a polarization versus electric field measurement of a PTO layer produced in accordance with an embodiment of the invention;

FIG. 18 is a scanning electron microscope (SEM) image of a trench formed in silicon that has been conformally coated with a layer of PZT produced in accordance with an embodiment of the present invention; and

Table 1 lists ferroelectric properties of a PTO layer produced using an embodiment of the present invention.

Table 2 lists ferroelectric properties of a PZT layer produced using an embodiment of the present invention.

### DETAILED DESCRIPTION

Embodiments of the invention utilize a commercially viable process comprising a specific combination of precursors (in particular, Pb(DMAMP)₂ and amide 4+ cation precursors), a particular process temperature window, a particular precursor pulse-sequence, and a particular post-processing which yields a technologically useful phase of lead titanate (PTO), lead zirconate (PZO), and lead zirconate titanate (PZT). Embodiments of the invention further include methods to control the texture of the deposited films.

Embodiments of the invention include the specific administration of an atomic layer deposition (ALD) process that yields high-quality lead titanate (PTO), lead zirconate (PZO), and lead zirconate titanate (PZT) films following a post-deposition anneal. This process produces PTO, PZO or PZT films, whereby growth of the film occurs primarily due to self-limited surface chemisorption of pulsed chemical vapor. Four chemical precursors are used in the preparation of the film including Pb(DMAMP)₂, TDMAT, TDMAZ, and H₂O. The precursors Pb(DMAMP)₂, TDMAT, and TDMAZ supply the lead, titanium and zirconium cations, respectively, though other precursors could be substituted to reveal other compatible combinations. H₂O is the oxidizing species for each metal cation precursor in the deposition sequence, though other oxidizers would be compatible including but not limited to H₂O₂ and O₃. Co-oxidizers may also be used, e.g., a sequence of H₂O and O₃, or O₃ followed by H₂O, or applying both oxidizers simultaneously.

The precursors are heated in order to supply sufficient vapor pressure for deposition with the exception of H₂O which has sufficient vapor pressure at room temperature. The Pb(DMAMP)₂ precursor is nominally heated to 80° C. and would work in the range of 50° C. to 100° C. TDMAT is nominally heated to 85° C. and would work in the range of 0° C. to 90° C., TDMAZ is nominally heated to 75° C. but would work in the range of 40° C. to 85° C. The film is deposited by sequentially pulsing the precursors into an appropriate reactor, and each pulse is separated by a purge step to ensure the reactor has been fully evacuated before the introduction of the subsequent precursor. The purge step typically involves flowing an inert gas, typically nitrogen or argon, through the reactor while simultaneously pumping downstream with an ALD process pump. Depending on the reactor design it may be desirable to only pump on the reactor without flowing inert gas during the purge step.

The PTO, PZO, and PZT films are deposited by repetitive sequencing of ALD cycles corresponding to the constituent oxides of TiOₓ, ZrOₓ, and PbOₓ. With each cycle, material growth occurs primarily due to self-limited surface chemisorption of pulsed chemical vapor. In one embodiment, one ALD cycle is defined as follows: one 0.5 second cation precursor pulse step, followed by a 10 second reactor purge step, followed by one 0.5 second oxidizing precursor pulse step and finishing with one 10 second reactor purge step. The exact duration of each dose/purge step will vary depending on individual reactor dynamics and the precursor used. The precursor dose may be increased either by increasing the dose time above 0.5 seconds, increasing the precursor temperature, or by adding additional pulses of the same precursor in series before the purge step. The use of a 0.5 second precursor pulse and a 10 second purge step is considered an exemplary embodiment of the invention. Other length pulses may be used, for example, the precursor pulse may range from 0.05 seconds to 30 seconds and the purge step could range from 1 seconds to 60 seconds. The specific selection of the pulse and step lengths to use are well within the skill in the art to derive in view of the materials used, the film type to be deposited and the desired thickness of the film.

Although ALD is discussed as one specific way of depositing the PZO, PTO, or PZT film, other forms of conformal deposition such as pulsed chemical vapor deposition may be utilized. The commonality of these types of deposition techniques all utilize pulses of chemical vapor to achieve a desired film thickness.

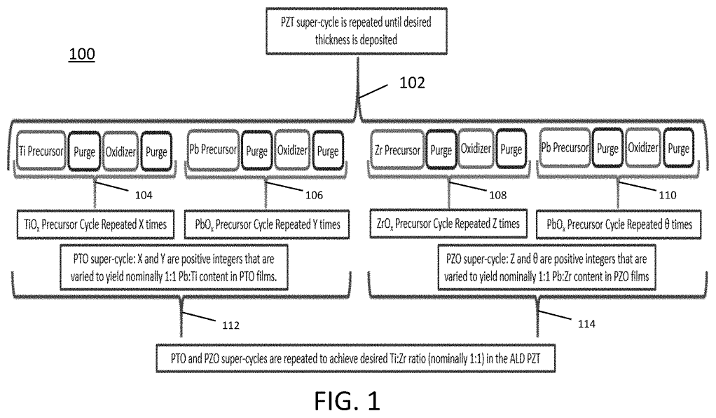

The chemical vapor pulsing cycles described above are combined to form a super-cycle according to FIG. 1.

FIG. 1 depicts a process 100 for the deposited PZT films. The stoichiometry can be varied by adjusting the ratio of PTO:PZO super-cycles, and the stoichiometry of the PTO or PZO films can be varied by adjusting the ratio of TiOₓ:PbOₓ or ZrOₓ:PbOₓ ALD cycles within the super-cycles. The overall film thickness of the PTO, PZO, and PZT is determined by the number of repetitions of the super-cycles.

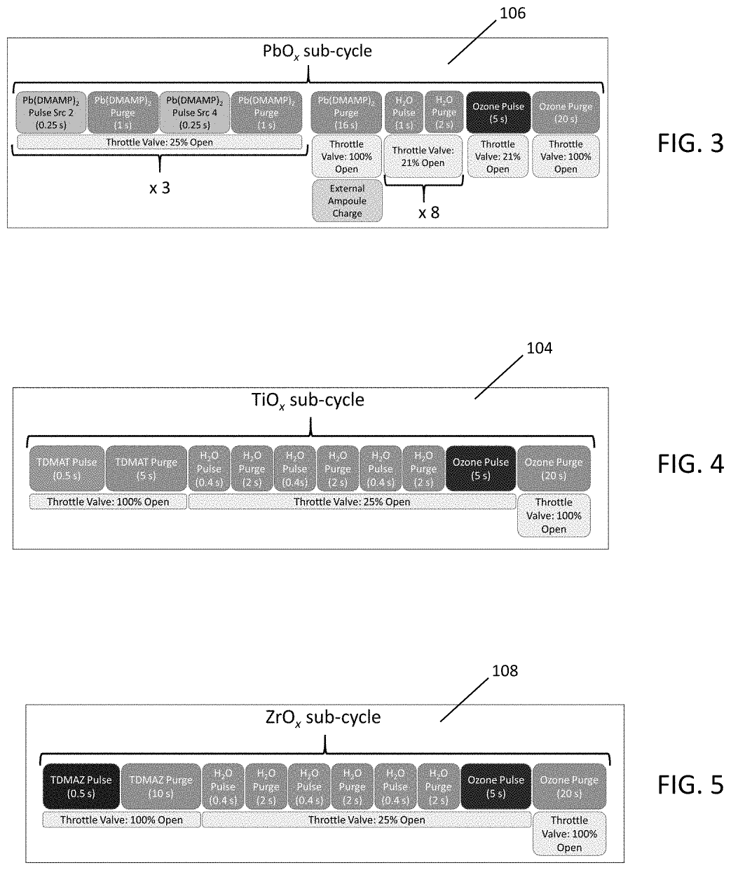

FIG. 1 depicts a super-cycle 102 for PZT deposition comprises a plurality of sub-cycles 104, 106, 108, and 110. Sub-cycle 104 is a TiOₓ precursor cycle that is repeated X times (X being a positive integer) to obtain a required thickness of TiOₓ on the substrate. The sub-cycle 104 comprises, as mentioned above, a sequence of steps performed within a chamber comprising: a Ti precursor step, a purge step, an oxidizer step, and a final purge step. Sub-cycle 106 is a PbOₓ precursor cycle that is repeated Y times (Y being a positive integer) to obtain a required thickness of PbOₓ. The sub-cycle 106 comprises, as mentioned above, a sequence of steps performed within a chamber comprising: a Pb precursor step, a purge step, an oxidizer step, and a final purge step. The sub-cycles 104 and 106 together form a super-cycle 112 that is used to yield a nominally 1:1 ratio of Pb and Ti content in a PTO film. The ratio is achieved by adjusting the values of X and Y. Specific details of the PbOₓ, TiOₓ, and ZrOₓ sub-cycles are provided below with respect to FIGS. 3, 4, and 5.

Sub-cycle 108 is a ZrOₓ precursor cycle that is repeated Z times (Z being a positive integer) to obtain a required thickness of ZrOₓ on the substrate. The sub-cycle 108 comprises, as mentioned above, a sequence of steps performed within a chamber comprising: a Zr precursor step, a purge step, an oxidizer step, and a final purge step. Sub-cycle 110 is a PbOₓ precursor cycle that is repeated 8 times (8 being a positive integer) to obtain a required thickness of PbOₓ. The sub-cycle 110 comprises, as mentioned above, a sequence of steps performed within a chamber comprising: a Pb precursor step, a purge step, an oxidizer step, and a final purge step. The sub-cycles 108 and 110 together form a super-cycle 114 that is used to yield a nominally 1:1 ratio of Pb and Zr content in a PZO film. The ratio is achieved by adjusting the values of Z and θ.

The PZT super-cycle 102 comprises the PTO and PZO super-cycles 112 and 114. As each sub-cycle is executed to deposit defined amounts of Pb, Ti, and Zr and adjusting the number of cycles performed as PTO and PZO super-cycles, the result is a desired ratio of Ti:Zr (nominally 1:1) in the overall PZT film, though elemental gradients could be engineered by modification of the layering sequence.

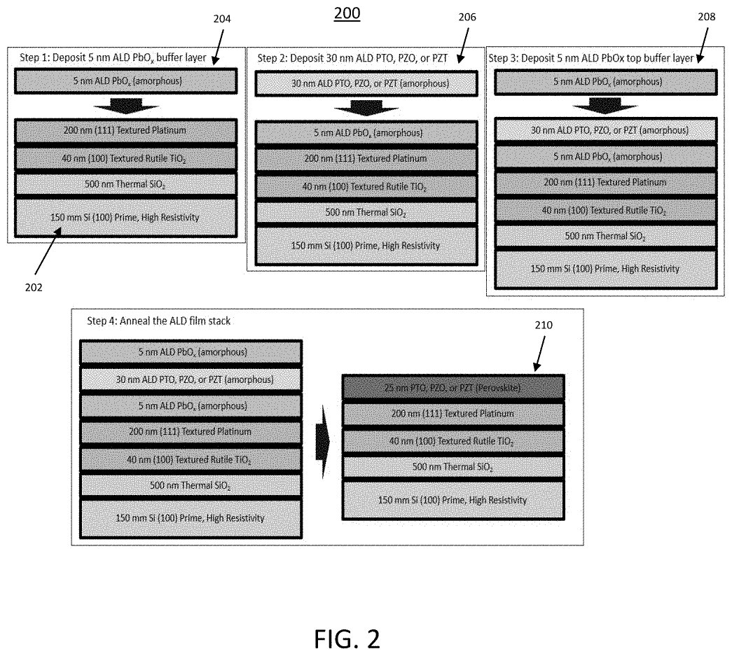

FIG. 2 depicts the ALD process flow 200 using the process 100 of FIG. 1 to form a PZT, PTO, or PZO film upon a substrate 202. The substrate 202 is of importance to ALD processes and MEMS devices. In one embodiment, the substrate 202 is a 100 nm (111) oriented platinum film deposited on textured TiO₂ adhesion layer which has been deposited onto a thermal SiO₂ coating on a buffered silicon wafer. This stack of silicon wafer, SiO₂, TiO₂, and platinum is referred to herein as the substrate 202.

In one embodiment of the invention, the substrate temperature during ALD sequence is held at 200° C. However, the process will work within the range to 150° C. to 350° C.

FIG. 2 depicts a four-step process for depositing PTO, PZO or PZT upon the substrate and then annealing the film stack to create a uniform PTO, PZO or PZT film on the substrate 202. Steps 1 and 3 are deemed optional, wherein 5 nm ALD PbOx layers are deposited to serve to increase the lead concentration at the interfaces of the PTO, PZO, or PZT deposition to promote nucleation.

Specifically, at step 1, the optional 5 nm buffer layer 204 of PbOₓ is deposited using the PbOₓ sub-cycle 106 of FIG. 1. At step 2, a 30 nm thick layer 206 of PTO, PZO or PZT is deposited over the PbOₓ buffer layer 204 using the sub-cycles and super-cycles of FIG. 1. At step 3, the optional 5 nm buffer layer 208 of PbOₓ is deposited over the PTO, PZO, or PZT layer using the PbOₓ sub-cycle 106 of FIG. 1. All the deposited layers 204, 206 and 208 are amorphous.

At step 4 of process 200, the film stack of 202, 204, 206, 208 is annealed to produce a 25 nm thick layer 210 of PTO, PZO, or PZT having a perovskite structure. The anneal step may be performed in a rapid thermal anneal (RTA) oven, a heated substrate chuck (hot chuck) under vacuum or O₂ ambient, or other common anneal methods. The anneal process conditions are as follows for both the hot chuck and RTA methods: the maximum temperature range would be 500° C. to 800° C., the anneal time can vary between 0 seconds and 4 hours, and the O₂ flow can vary between 0 liters per minute to 100 liters per minute.

Texture control may be obtained by fabricating thin nucleation layers designed to template further growth. The nucleation layers are fabricated by first depositing 0-5 nm of ALD TiOₓ followed by 0-10 nm ALD PbOₓ followed by an annealing step. Two examples of annealing techniques would be rapid thermal anneal with an oxygen environment, or a hot chuck contained within a vacuum system with gas and pressure control. Identical to the above, the anneal conditions for the nucleation layers are as follows for both the hot chuck and RTA methods: the maximum temperature range would be 500° C. to 800° C., the anneal time can vary between 0 seconds and 4 hours, and the O₂ flow can vary between 0 liters per minute to 100 liters per minute.

FIG. 3 depicts a more detailed view of the PbOₓ sub-cycle 106 described above for a specific embodiment of the invention, FIG. 4 depicts a more detailed view of the TiOₓ sub-cycle 104 described above for a specific embodiment of the invention, and FIG. 5 depicts a more detailed view of the ZrOₓ sub-cycle 108 described above for a specific embodiment of the invention. These sub-cycles, as a specific embodiment of the invention, comprise the specific sequences and timings of precursor applications that can be used in the super-cycle of FIG. 1 to produce conformal thin films (layers) of PTO, PZT, and PZO.

In one embodiment of the invention used to produce a PTO thin film, the PTO thin films were deposited by atomic layer deposition (ALD) using a Kurt J. Lesker Company ALD-150LX reactor. Laminar purge flow was constantly supplied using mass flow controller (MFC)-regulated ultrahigh purity (UHP) argon supplied by a cryogenic liquid argon dewar. The purge flow was used to provide a diffusion barrier to prevent deleterious chamber wall deposition and to serve as a carrier gas for the precursors. The process pressure was held at approximately 1.6 Torr. Pb(DMAMP)₂ heated to 90° C. and TDMAT heated to 85° C. in stainless steel ampoules were used as the lead and titanium cation precursors, respectively. TDMAT was selected due to its high vapor pressure when heated above 40° C. and high reactivity at substrate temperatures of 250° C. Pb(DMAMP)₂ was selected as the lead precursor due to its reasonable vapor pressure and the quality of the electrical properties demonstrated previously. The vapor pressure of the Pb(DMAMP)₂ was increased by briefly pulsing argon into the ampoule prior to dosing into the reactor. Demineralized H₂O at ambient temperature and ozone were both used as oxidizers. Ozone was supplied via an Absolute Ozone® Nano Ozone Generator. Ozone flow was controlled via MFC to 200 sccm, and the ozone concentration was measured to be approximately 10% by volume. The ozone generator was continuously running during the deposition process, and the ozone was collected in a 1 liter stainless steel reservoir which was evacuated into the reactor using an ALD valve during the ozone dose step. As depicted in FIG. 4, TDMAT was pulsed into the reactor for 0.5 seconds followed by a 20-second purge step prior to oxidation. H₂O was dosed using three sequential 1-second pulses to ensure saturation, followed by a 5-second ozone dose and a 20-second purge. Pb(DMAMP)₂ was pulsed into the reactor using six-sequential 0.25-second pulses followed by a 20-second purge and was oxidized using eight sequential 1-second H₂O pulses, followed by a 5-second ozone dose and a 20-second purge. No thickness change was observed using a Film Sense (Lincoln, Nebr., USA) FS-1™ multi-wavelength ellipsometer following the first pulse of either the H₂O or the Pb(DMAMP)₂; however, the additional pulses improved the cross-wafer thickness uniformity. The substrate temperature was held at 250° C. for all depositions. The substrates 202 were “platinum lower electrode film stacks”, each consisting of Si (150 mm substrate)/500 nm SiO₂ (elastic layer, thermal wet oxide)/40 nm TiO₂ (adhesion layer, sputtered Ti followed by furnace oxidation)/(bottom electrode, 100 nm Pt sputtered at 500° C.).

PTO growth was achieved using a combination of binary oxide processes for PbOₓ and TiOₓ with the relative number of PbOₓ:TiOₓ sub-cycles varied over the range from 1:1 to 4:1. The cycle ratio refers to the relative number of PbOₓ to TiOₓ cycles in one super-cycle, which is repeated to achieve the desired thickness. For example, PTO films grown with a 3:1 PbOₓ:TiOₓ cycle ratio indicates that the super-cycle consists of three PbOₓ ALD cycles performed in sequence followed by a single TiOₓ cycle. The films grown with fractional cycle ratios such as 3:2 and 5:2 are grown with the constituent binary ALD cycles occurring in back-to-back sequence as follows: (PbOₓ)x3-(TiOₓ)x2 for 3:2 and (PbOₓ)x5-(TiOₓ)x2 for 5:2.

In an exemplary embodiment of the invention, the PTO films were annealed by rapid thermal anneal (RTA) at 700° C. for 1 minute with a 90° C./sec standard ramp rate in O₂ atmosphere using an AG Associates 610 system for crystallization prior to electrical characterization. The sample temperature was measured by a thermocouple in contact with the backside of the substrate near the center of the RTA. Each sample selected for electrical characterization received at least one additional deposition layer and anneal to help to avoid electrical shorting due to pinholes. A 50-nm Pt thin film, sputtered at 500° C. to promote adhesion, was used as the top electrode. Capacitors with 4.92×10⁻⁴ cm² area were patterned using photolithography, and the electrode area was defined using UV-stabilized resist and etched via ion milling. The capacitor array was evenly spaced over a 100-mm diameter working area. In other embodiments, additional piece-part samples were annealed for varying times, temperatures, and ramp rates in an Allwin 21 810 RTA using a carrier wafer to evaluate a variety of thermal treatment recipes.

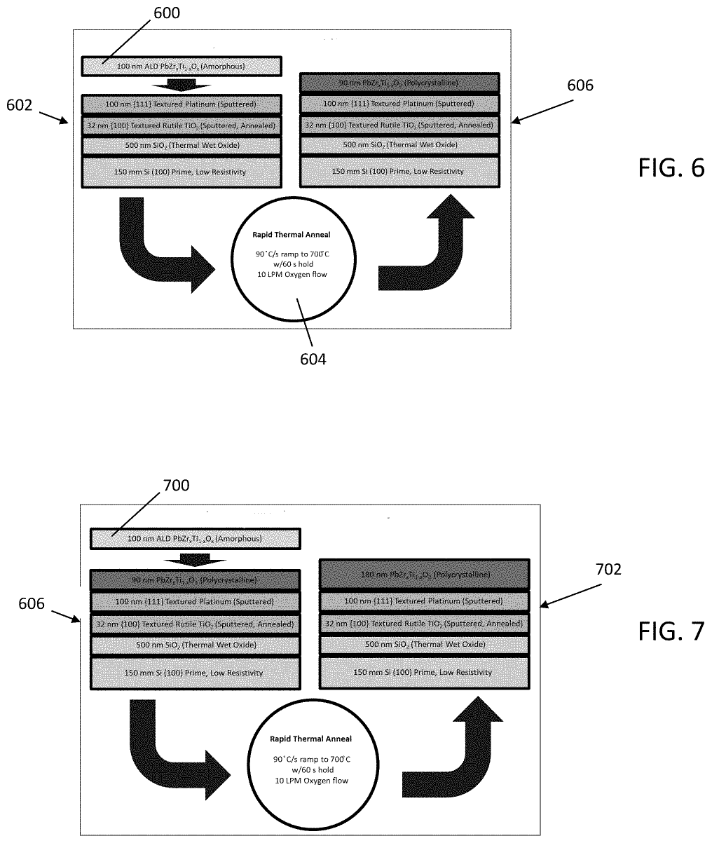

FIG. 6 graphically represents the rapid thermal anneal step for the process described above. Here, the PTO, PZO, or PZT layer 600 is deposited onto a substrate 602 formed of a stack comprising 150 mm of silicon (a base wafer), 500 nm of SiO₂, 32 nm of textured rutile TiO₂, and 100 nm of textured platinum (Pt). The sub-cycle/super-cycle process described above is then used to deposit an amorphous, nominally 100 nm-thick PTO, PZO, or PZT layer 600. This stack comprising 600 and 602 is then annealed at step 604 to change the amorphous 100 nm PTO, PZO, or PZT layer 600 into a polycrystalline layer of PTO, PZO, or PZT 606, which may roughened or shrunk from the crystallization process.

FIG. 7 graphically depicts a repeat of the process of FIG. 6 using the substrate with the polyscrystalline layer 606 of PTO, PZO, or PZT as the starting point for the next deposition of an amorphous PTO, PZO, or PZT layer 700. As such, a thicker PTO, PZO, or PZT layer is produced. After two cycles there is nominally 180 nm of PTO, PZO, or PZT in the post annealed stack 702. Further repetition of the process could be performed to increase the thickness of the PZT, PTO, or PZO layers.

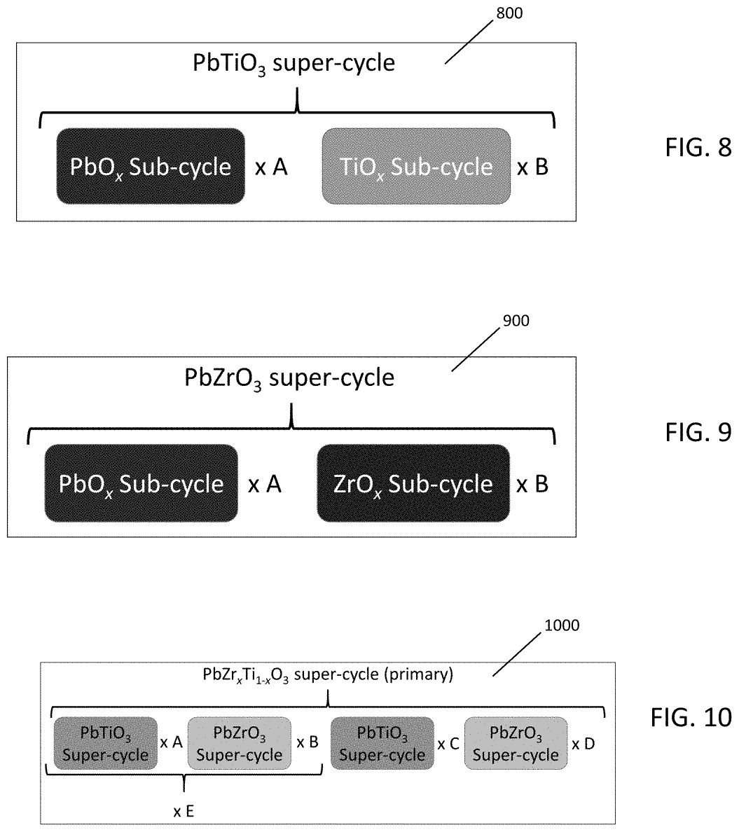

FIG. 8 is a representation of a PbTiO₃ super-cycle 800 that combines the PbOₓ and TiOₓ sub-cycles in accordance with an embodiment of the invention, FIG. 9 is a representation of a PbZrO₃ super-cycle 900 that combines the PbOₓ and ZrOₓ sub-cycles in accordance with an embodiment of the invention, and FIG. 10 is a representation of a PbZrₓTi₁₋ₓO₃ super-cycle 1000 that comprises the PbZrO₃ super-cycle and the PbTiO₃ super-cycle in accordance with an embodiment of the invention. These super-cycles are created by repeating the constituent sub-cycles as described above. Specifically, as shown in FIG. 8, the PbTiO₃ super-cycle 800 is created by repeating the PbOₓ sub-cycle an “A” number of times and repeating the TiOₓ sub-cycle a “B” number of times. Similarly, as shown in FIG. 9, the PbZrO₃ super-cycle 900 is created by repeating the PbOₓ sub-cycle an “A” number of times and repeating the ZrOₓ sub-cycle a “B” number of times. As shown in FIG. 10, a PbZrₓTi₁₋ₓO₃ super-cycle 1000 is comprised of repeating the PbTiO₃ super-cycle and the PbZrO₃ to form the desired PZT layer.

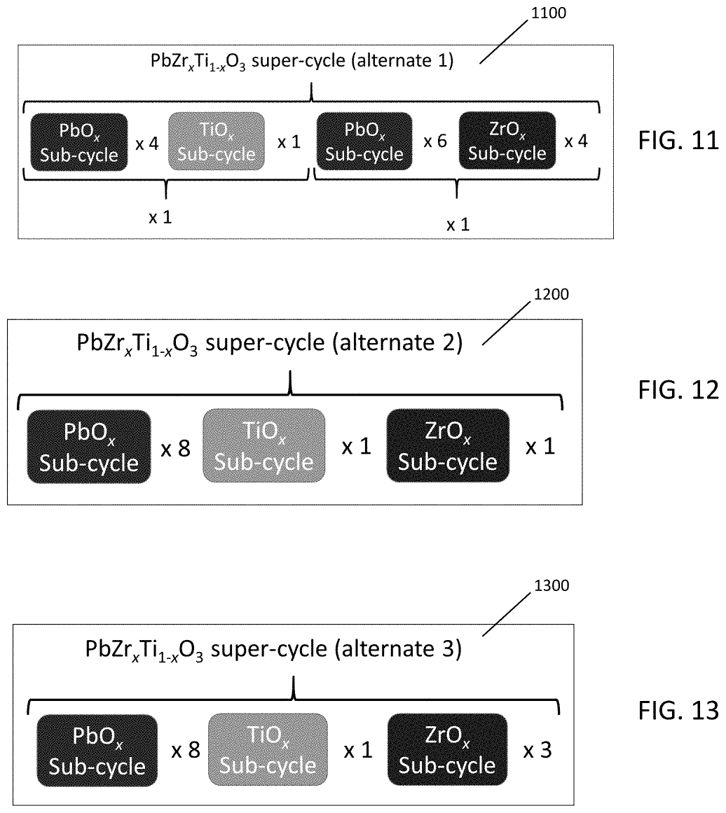

FIG. 11 depicts a specific PbZrₓTi₁₋ₓO₃ super-cycle 1100 embodiment where the PbOₓ sub-cycle is repeated four times followed by a TiOₓ sub-cycle that is performed once. This deposition is followed by repeating the PbOₓ sub-cycle six times and the ZrOₓ sub-cycle four times. FIG. 12 depicts an alternative embodiment for producing a PbZrₓTi₁₋ₓO₃ super-cycle 1200 comprising repeating the PbOₓ sub-cycle eight times followed by a single deposited layer from the TiOₓ and ZrOₓ sub-cycles. FIG. 13 depicts a further alternative embodiment for producing a PbZrₓTi₁₋ₓO₃ super-cycle 1300 comprising repeating the PbOₓ sub-cycle eight times followed by a single deposited layer from the TiOₓ sub-cycle and three cycles through the ZrOₓ sub-cycle. Those skilled in the art will be able to determine many other sub-cycle combinations that are within the scope of the present invention.

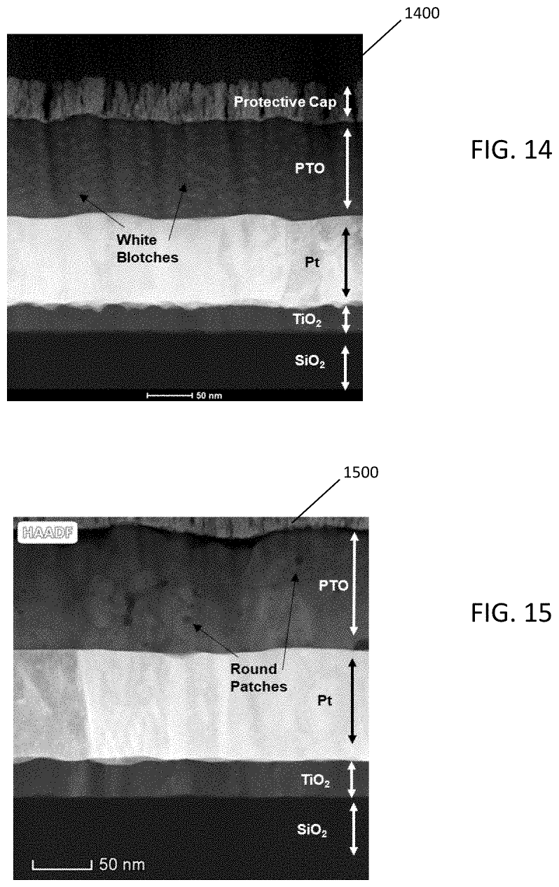

FIG. 14 depicts a STEM image obtained for a PTO sample 1500 deposited with a PbOₓ:TiOₓ ratio of 3:1. The sample 1400 is shown as-deposited (no anneal) in FIG. 14. The as-deposited ALD PTO film is smooth as-deposited with the surface roughness nearly matching the underlying substrate. Grain boundaries are not apparent in the PTO layer at the stated resolution, which implies that the film is not fully crystallized as-deposited. Unlike the Pt, TiO₂, and SiO₂ substrate layers, the PTO layer has finely clustered regions of differing contrast. The HAADF detector provides z-contrast that shows heavy elements brighter and lighter elements darker. The difference in contrast within the PTO layer implies that there is a segregation of the Pb and Ti cations on the nm-scale. The white nm-scale clusters approximately 2-5 nm in diameter likely correspond to the PbOₓ phases previously identified by XRD in section B2 because Pb is far heavier than Ti. Metallic Pb can be ruled out because the RBS analysis showed that the as-deposited films contained 62 (±3) at % O₂, which indicates that the films were fully oxidized before the anneal.

FIG. 15 shows the microstructure of the annealed ALD PTO sample. The protective cap was deposited in the FIB after the PTO film was annealed and therefore did not influence the crystallization. The apparent delamination of the protective cap is due to either poor adhesion of the as-deposited PTO, or FIB damage during sample preparation. Grain boundaries are readily observed in the PTO film and indicate that the PTO film crystallized upon RTA treatment. The grains appear to be distributed at random with diameters ranging from approximately 10-50 nm. None of the grains in contact with the lower Pt electrode appear to extend through the entire film thickness, which suggests that the grains nucleated throughout the film and that the nucleation was not localized to the Pt-PTO interface. This is in distinct contrast to the columnar growth observed for sputtered and sol-gel PZT films where grains nucleate primarily at the lower electrode-PZT interface and extend to the top electrode. The difference in nucleation mode explains why the TiOₓ and PbOₓ nucleation layers did not strongly influence the texture of the crystallized films. Only the minority fraction of grains that nucleated at the Pt/PTO interface could be directly affected by the nucleation layers, therefore the orientation of the PTO grains was not strongly influenced by the substrate.

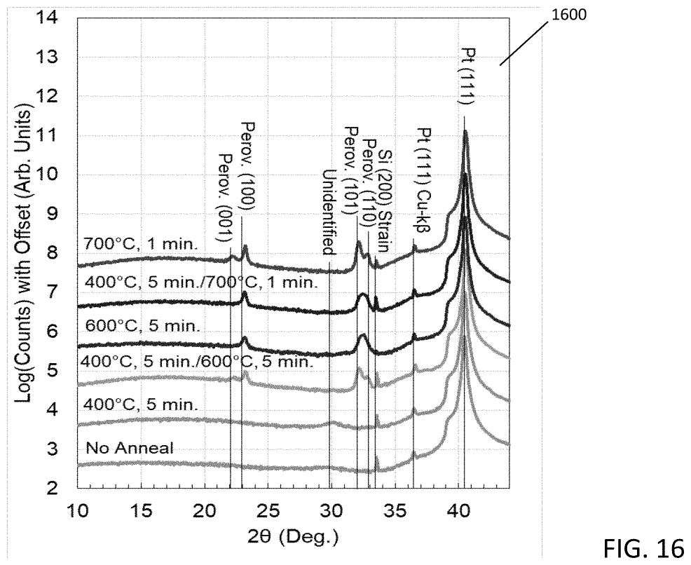

FIG. 16 is a graph 1600 of X-Ray diffraction produced by a PTO layer created using several different anneal protocols in accordance with an embodiment of the invention. The as-grown films appear to crystallize into the desired perovskite phase if the maximum annealing temperature falls within the range of 600-700° C. The variation of final crystallization temperature and time did not seem to strongly affect the phase or orientation of the crystallized PTO films.

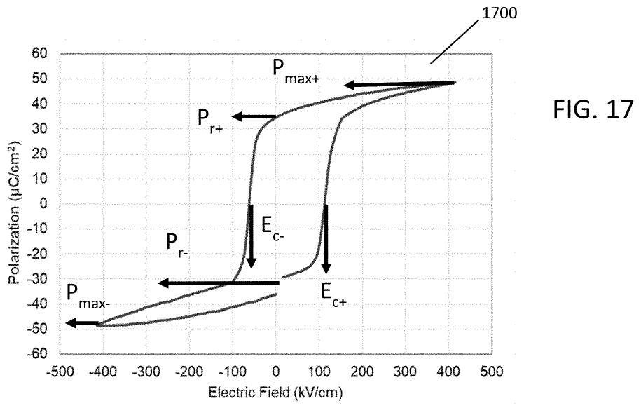

FIG. 17 is a polarization vs. electric field graph 1700 comprising nested polarization/electric-field loops for a PTO sample having 5604 ALD cycles divided into four equal sets of coatings, each followed by a rapid thermal anneal. The final film thickness was 360 nm. The sample displays a maximum polarization (Pₘₐₓ) 48 μC/cm² when tested at 415 kV/cm (15V), remnant polarization (2Pr)=60 μC/cm², and coercive fields E_{c1}=−73 kV/cm and E_{c2}=125 kV/cm.

Table 1 summarizes the properties of the PTO film of FIG. 17. Table 2 summarizes the properties of a PZT film fabricated in accordance with an embodiment of the invention.

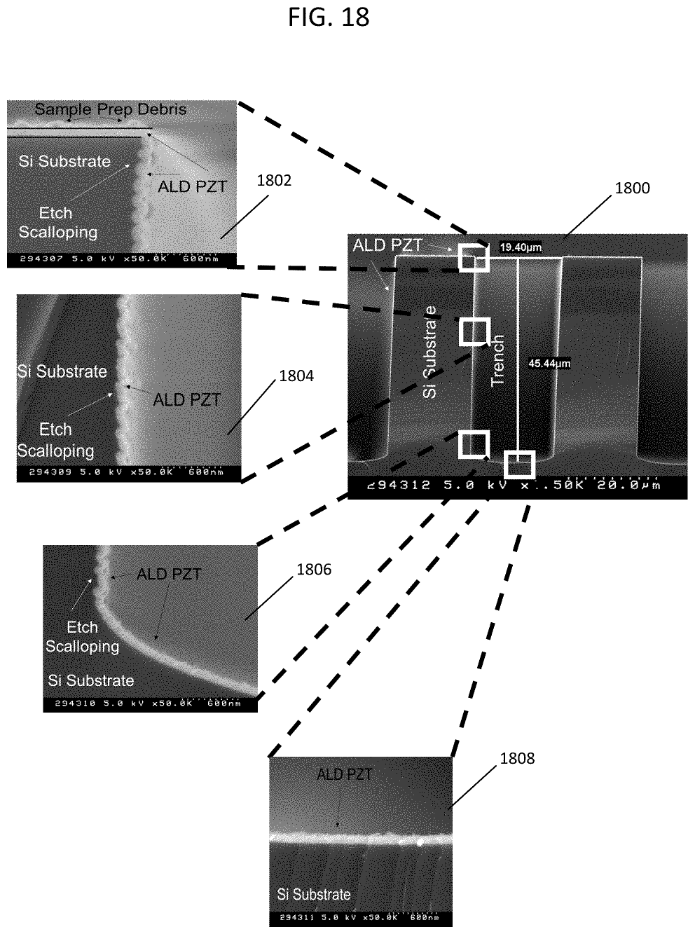

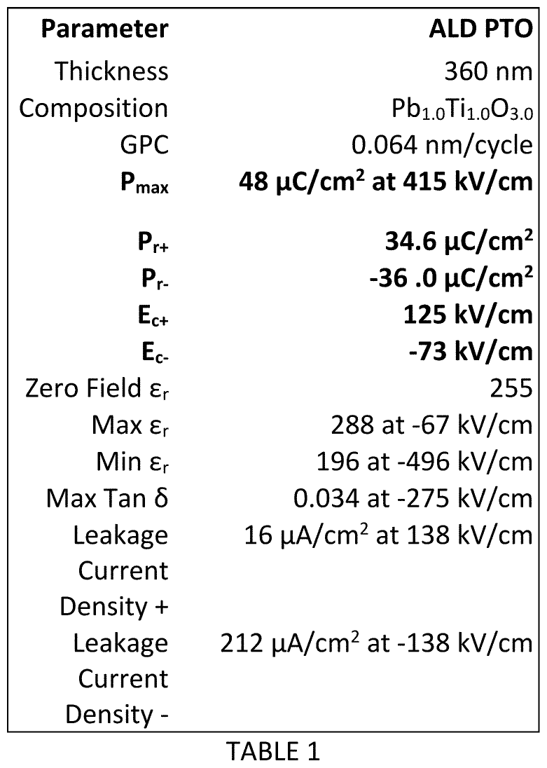

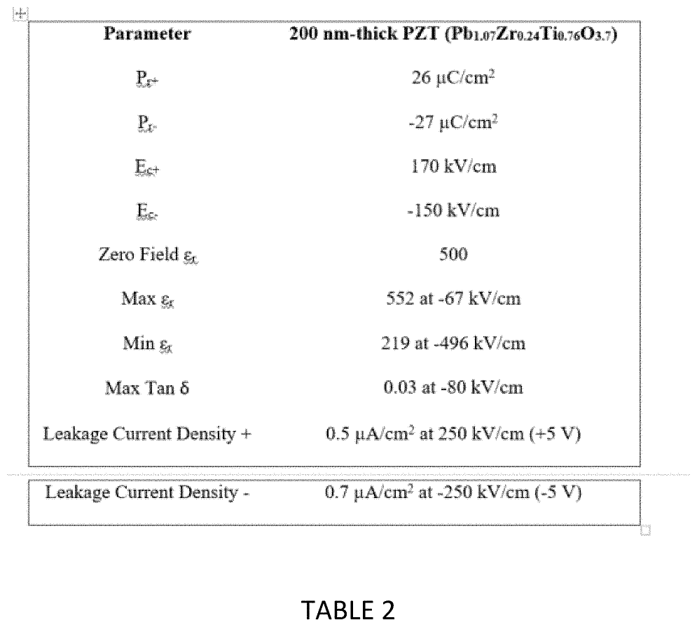

FIG. 18 is an SEM image 1800 of a trench formed in silicon that has been conformally coated with a layer of PZT produced in accordance with an embodiment of the present invention. The sub-images 1802, 1804, 1806, and 1808 depict specific areas of the trench to show the substantial conformity of the PZT deposit in all areas of the trench. Specifically, sub-image 1802 depicts a close-up, cross-sectional view of the top corner of the trench, sub-mage 1804 depicts a close-up, cross-sectional view of the sidewall of the trench, sub-mage 1806 depicts a close-up, cross-sectional view of the bottom corner of the trench, and sub-mage 1808 depicts a close-up, cross-sectional view of the bottom of the trench. In all instances, the PZT formed in accordance with an embodiment of the invention has very conformal properties.

Generally atomic layer deposition is a technique designed to improve the areal utilization of substrates. In the context of electronics manufacturing, substrates are typically thin wafers of a structural material, often silicon, sized from 150 to 350 mm in diameter and typically around 1 mm thick. Taking the simple case of square capacitor, nominally 50 microns×50 microns in area and 1 micron thick, there is an obvious limit to the number of capacitors than can fit on a single substrate if they are in the plane of the wafer. However, trenches could be patterned and etched such that the capacitors could be fabricated vertically, 40-50 capacitors could fit on the same area as a single in-plane capacitor, increasing the number of active devices on a single wafer by more than an order of magnitude. A further example that may use the conformal deposition technique described herein includes the three-dimensional MEMS device described in commonly assigned U.S. Pat. No. 8,966,993, granted Mar. 3, 2015, and hereby incorporated herein in its entirety.

In the extreme case, nanotubular structures could be coated using the ALD technique described herein.

The capacitor is not an arbitrary example, as PTO and PZT are both ferroelectric materials that could be incorporated into a 3D capacitor design. In fact, Texas Instruments (TI) utilizes PZT for non-volatile ferroelectric random access memory units with 50 ms read/write speeds, which are essentially capacitors arrayed into a memory architecture. Currently TI uses Metal Organic Chemical Vapor Deposition (MOCVD) to deposit PZT, though MOCVD is primarily a planar technique incapable of coating high aspect-ratio topologies. The areal density could be greatly improved with a robust technique to deposit PZT by ALD. Commercially available FRAM products are typically low in capacity (2-4 MB), which limits the overall integration into consumer electronics.

In other embodiments, 3D deposition of PZT by ALD is needed to improve actuation force, efficiency, and density of MEMS structures as we attempt to modernize technologies such as electromechanical actuators, gyroscopes, and resonators. Embodiments of the invention greatly enhance the signal or actuation force density per unit area of many microelectromechanical systems that employ PZT as the piezoelectric material such as transducers, actuators, benders, or resonators. The high aspect ratio characteristic of this approach could significantly enhance the dynamic range of MEMS fabricated gyroscopes used in inertial measurement units thereby providing a more stable navigation solution for assured position, navigation, and timing (PNT). Additionally, the revolutionary new actuator performance would enable high mobility mm-scale robotics for emergency search and recovery.

Another benefit is that the technique permits the tailoring of film growth by manipulation of surface chemistries. Chemical precursors are used in some cases to promote film nucleation on certain surfaces while preventing nucleation on others. ALD could potentially replace sol-gel, sputtering, pulsed-laser deposition (PLD), and MOCVD as a more efficient method even for planar device architectures by reducing the number of required lithographic masks and etch steps by making use of surface selective deposition.

Embodiments of the invention display superior results in the following exemplary ways: the XRD evidence provided for PTO deposited by ALD incontrovertibly shows the perovskite phase with no deleterious phases, the nominal growth rate is high with an ideal sub-cycle ratio of one lead dose cycle to one titanium dose cycle required for perovskite films, and finally texture control has not been observed in any of the PTO, PZO, or PZT as-deposited obtained by ALD but has been attained with the proposed strategy.

Other technologies that may benefit from conformal layers of PZT include:
Microrobotics (lateral actuation);
Ink jet head manufacturing, replacing planar PZT deposition processes for printer ink-jet head manufacturing improving the performance per-unit-area;
Consumer grade inertial sensors for automotive industry;
Mobile Internet of Things Sensors, specifically acoustic, vibration, and motion;
PZT based MEMS speakers enabling immersive Dolby Atmos® compatible headphones for VR;
Energy harvesting wearables utilizing the piezoelectric effect;
2D and 3D conformal deposition of PZT for MEMS gyroscopes, actuators, resonators, speakers, and transducers;
2D and 3D conformal deposition of PZT to replace planar deposition techniques for ink-jet printer head manufacturing;
2D and 3D conformal deposition of PZT for use as a ferroelectric to replace MOCVD grown PZT for FRAM, enabling much higher storage capacities;
3D, conformal deposition of PZT for use as a ferroelectric in high surface area capacitors for energy storage applications; and
2D and 3D conformal deposition of PZT for use as a piezoelectric for energy harvesting.

While the foregoing is directed to embodiments of the present invention, other and further embodiments of the invention may be devised without departing from the basic scope thereof, and the scope thereof is determined by the claims that follow.

1. A method of depositing a thin film of lead titanate (PTO), lead zirconate (PZO) or lead zirconate titanate (PZT), the method comprising:
depositing a PTO, PZO or PZT layer upon a substrate whereby growth occurs primarily due to self-limited surface chemisorption of pulsed chemical vapor; and
annealing the PTO, PZO, or PZT layer and substrate.

2. The method of claim 1 wherein PTO, PZO, PZT material is deposited with elemental gradients throughout a thickness of the PTO, PZO, or PZT layer.

3. The method of claim 1 wherein the PTO, PZO, PZT layer is conformal to a surface of the substrate.

5. The method of claim 1 wherein the pulses of chemical vapor are precursors used in atomic layer deposition.

6. The method of claim 1 wherein the PTO, PZO, or PZT layer is a mixture of amorphous TiOₓ—ZrOₓ and crystalline PbO domains after deposition and has a perovskite structure after annealing.

7. The method of claim 1 wherein deposition of a PTO, PZO, or PZT layer further comprises repetitively sequencing atomic layer deposition cycles using constituent oxides of TiOₓ, ZrOₓ, and PbOₓ, respectively, as cation precursors.

8. The method of claim 7 wherein the sequencing further comprises one or more cation precursor pulse steps, followed by a reactor purge step, followed by one or more oxidizing precursor pulse steps and finishing with one reactor purge step.

9. The method of claim 8 wherein the oxidizing precursor is H₂O, O₃, H₂O₂, oxygen radical, or a sequence or combination thereof.

10. The method of claim 1 wherein the PTO, PZO, or PZT layer includes dopants.

11. The method of claim 10 wherein the dopants are at least one of Sr, La, Al, Mn, Nb, Zr.

12. The method of claim 1 wherein the substrate comprises micromachined features, high aspect-ratio trenches, high aspect ratio pores, 3D-printed scaffolds, nano- or meso-porous media, self-assembled features, or is elastic.

13. The method of claim 1 wherein the substrate comprises layers of Si, SiO₂, TiO₂, and platinum and the PTO, PZO, or PZT layer is deposited upon the platinum.

14. A method of depositing a thin film of lead titanate (PTO), lead zirconate (PZO), or lead zirconate titanate (PZT) material, the method comprising:
depositing a PTO, PZO, or PZT layer upon a substrate using atomic layer deposition; and
annealing the PTO, PZO, or PZT layer and substrate to crystallize the PTO, PZO, or PZT material, respectively.

15. The method of claim 14 wherein depositing of PTO, PZO, or PZT layer further comprises repetitively sequencing atomic layer deposition cycles using constituent oxides of TiOₓ, ZrOₓ, and PbOₓ, respectively as cation precursors.

16. The method of claim 14 wherein the sequencing further comprises one cation precursor pulse step, followed by a reactor purge step, followed by one oxidizing precursor pulse step, and finishing with one reactor purge step.

17. The method of claim 16 wherein the oxidizing precursor is H₂O, O₃, H₂O₂, oxygen radical, or a sequence or combination thereof.

18. The method of claim 16 wherein the cycles are repeated until layers of defined thicknesses are formed containing Ti, Zr, Pb, oxygen, and reaction byproducts.

19. The method of claim 14 wherein the annealing heats the PTO, PZO, or PZT layer and substrate at 500-800° C. to crystallize the PTO, PZO, or PZT material, respectively.

20. The method of claim 13 wherein the PTO, PZO, PZT material is deposited with elemental gradients throughout a thickness of the PTO, PZO, or PZT layer.
